(19) United States
(12) Patent Application Publication
(10) Pub. No.: US 2026/0005191 A1
(43) Pub. Date: Jan. 1, 2026

(54) Semiconductor Device and Method of Forming Interconnect Structure in HBM Module Using VFM

(71) Applicant: JCET STATS ChipPAC Korea Limited, Incheon (KR)

(72) Inventors: Minsung Lee, Incheon (KR); YeoJun Yun, Incheon (KR); HeeSoo Lee, Incheon (KR)

(73) Assignee: JCET STATS ChipPAC Korea Limited, Incheon (KR)

(21) Appl. No.: 18/789,346

(22) Filed: Jul. 30, 2024

Related U.S. Application Data
(63) Continuation-in-part of application No. 18/760,283, filed on Jul. 1, 2024.

(51) Int. Cl. H01L 23/00; H01L 21/56; H01L 23/31; H01L 23/538; H01L 25/065

(52) U.S. Cl. CPC H01L 24/81; H01L 24/16; H01L 24/17; H01L 25/0652; H01L 21/561; H01L 23/3107; H01L 23/538; H01L 2224/16146; H01L 2224/16221; H01L 2224/17181; H01L 2224/81024; H01L 2224/81097; H01L 2224/8122

(57) ABSTRACT

A semiconductor device has a first electrical component and a second electrical component. A hybrid flux material is deposited over the first electrical component and/or second electrical component. The hybrid flux material can be a flux material with a non-conductive film or non-conductive paste. The second electrical component is stacked over the first electrical component. The first electrical component can be a semiconductor wafer or semiconductor die, and the second electrical component can be a semiconductor wafer or semiconductor die. An interconnect structure is formed between the first electrical component and second electrical component using a VFM signal. Heat can be applied during or after the VFM signal. The interconnect structure can be a bump. An encapsulant is deposited over the first electrical component and second electrical component. The encapsulated and stacked electrical components can be mounted to an interconnect substrate as a HBM module.

### CLAIM OF DOMESTIC PRIORITY

The present application is a continuation-in-part of U.S. patent application Ser. No. 18/760,283, filed Jul. 1, 2024, which application is incorporated herein by reference.

### FIELD OF THE INVENTION

The present invention relates in general to semiconductor devices and, more particularly, to a semiconductor device and method of forming an interconnect structure in a high bandwidth memory (HBM) module using VFM.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Multiple semiconductor wafers or individual semiconductor die can be stacked in a semiconductor package, commonly known as 3D integration. In particular, products such as integrating logic and memory circuits, sensor packaging, and combining micro electromechanical system (MEMS) with complementary metal oxide semiconductors (CMOS) use 3D integration to reduce the form factor, enhance performance, lower power consumption, increase integration capacity, and reduce costs.

The interconnect structure, e.g., bumps and conductive pillars, between stacked components in 3D integration is commonly done by thermal-compression bonding (TCB). TCB bonding uses heat and pressure to bond materials, typically thin films or layers. The heat softens the materials, and the pressure makes intimate contact between them, allowing bonds to form. However, if the heat and pressure are not uniformly transferred, potentially due to structural limitations, the interconnect structure can fail. Heat and pressure can become non-uniform, particularly for the interconnect structures at the top of the stack or furthest away from the heat source. A failure of the interconnect structure can cause the stacked wafer or die to tilt, slip, or warp, leading to defects and reduced reliability.

### BRIEF DESCRIPTION OF THE DRAWINGS

FIGS. 1a-1f illustrate a semiconductor wafer with a plurality of semiconductor die separated by a saw street;

FIGS. 2a-20 illustrate a process of bonding a plurality of stacked electrical components using VFM;

FIGS. 3a-31 illustrate a process of bonding a plurality of stacked electrical components over a semiconductor wafer using VFM;

FIGS. 4a-4f illustrate a process of bonding a plurality of stacked semiconductor wafers using VFM; and

FIG. 5 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

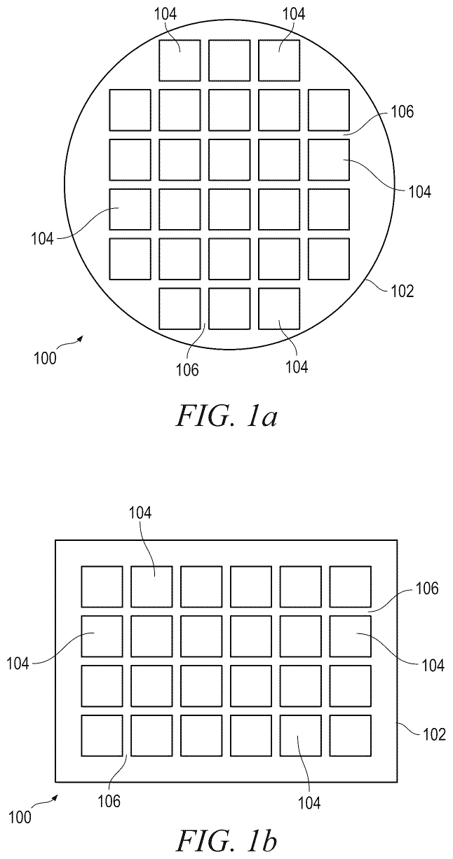

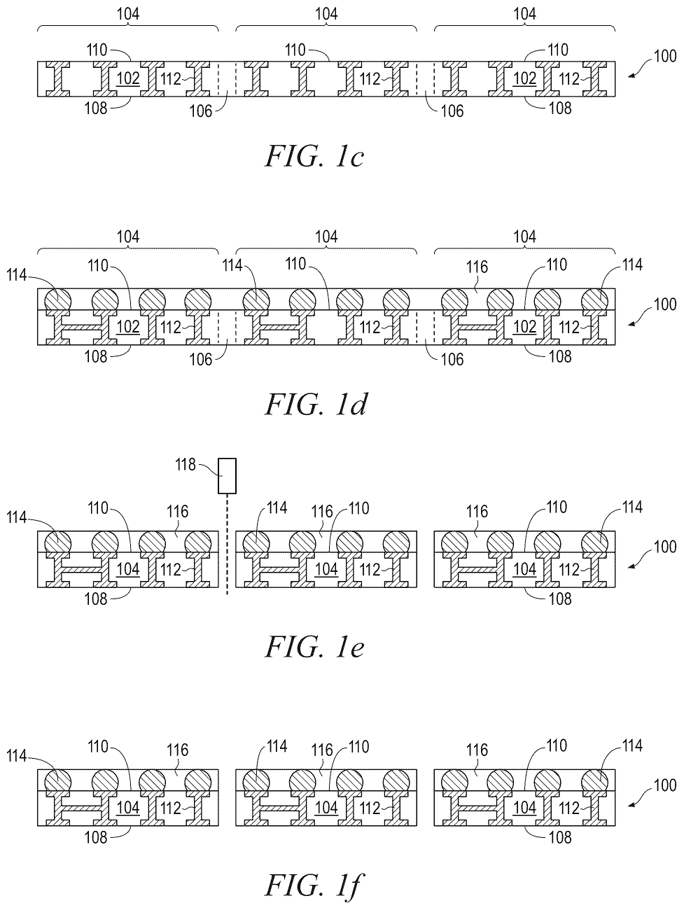

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 is circular with a diameter of 100-450 millimeters (mm). Semiconductor wafer 100 can be rectangular, as shown in FIG. 1b, or any other geometric shape.

FIG. 1c shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), or other signal processing circuit. Semiconductor die 104 may also contain IPDs, such as inductors, capacitors, and resistors, for RF signal processing. In one embodiment, semiconductor die 104 is a memory component.

A photoresist layer deposited over semiconductor wafer 100. The photoresist layer is patterned and etched according to the intended locations of conductive vias extending through base material 102. The openings in the photoresist layer are filled with one or more layers of aluminum (Al), copper (Cu), tin (Sn), nickel (Ni), gold (Au), to form conductive layer/vias 112.

Another portion of electrically conductive layer 112 is formed over active surface 110, as well as back surface 108, using PVD, CVD, electrolytic plating, electroless plating process, or other suitable metal deposition process. Conductive layer 112 can be one or more layers of Al, Cu, Sn, Ni, Au, Ag, or other suitable electrically conductive material. Conductive layer 112 operates as contact pads electrically connected to the circuits on active surface 110.

In FIG. 1d, an electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

A hybrid flux material 116 is deposited over active surface 110 and bumps 114. In one embodiment, hybrid flux material 116 is a combination of flux material with a non-conductive film (NCF), non-conductive paste (NCP), and/or epoxy. Hybrid flux material 116 is a polar material.

In FIG. 1e, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

FIG. 1f shows semiconductor die 104 with hybrid flux material 116 post singulation.

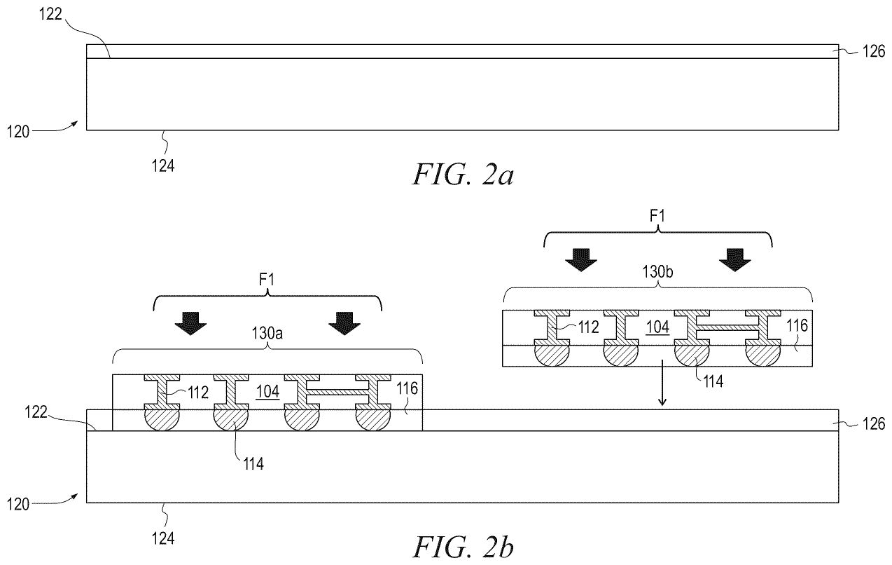

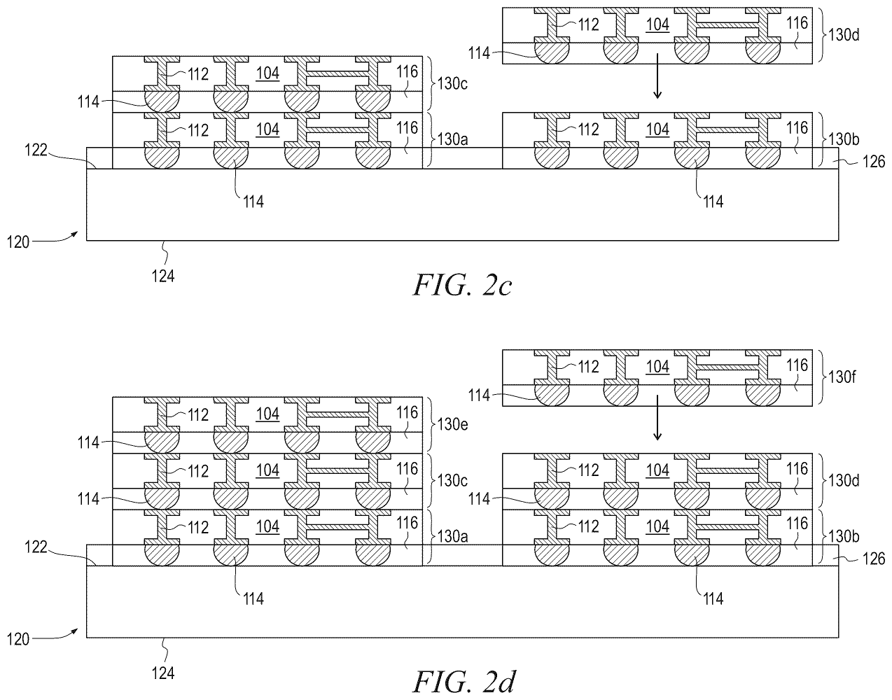

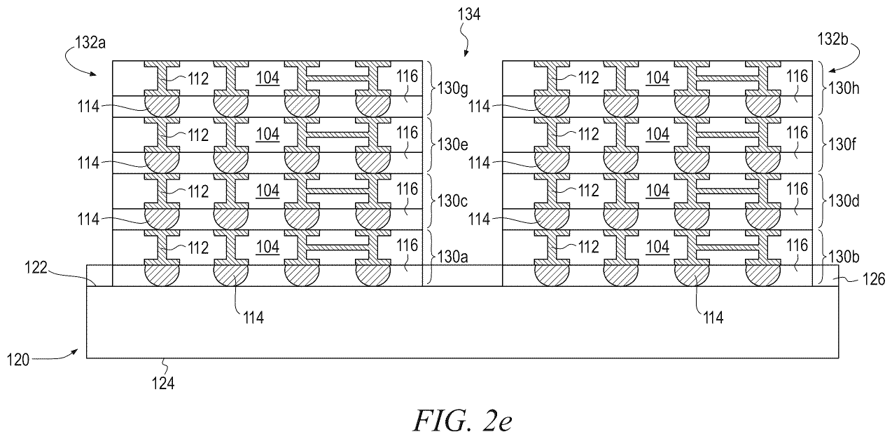

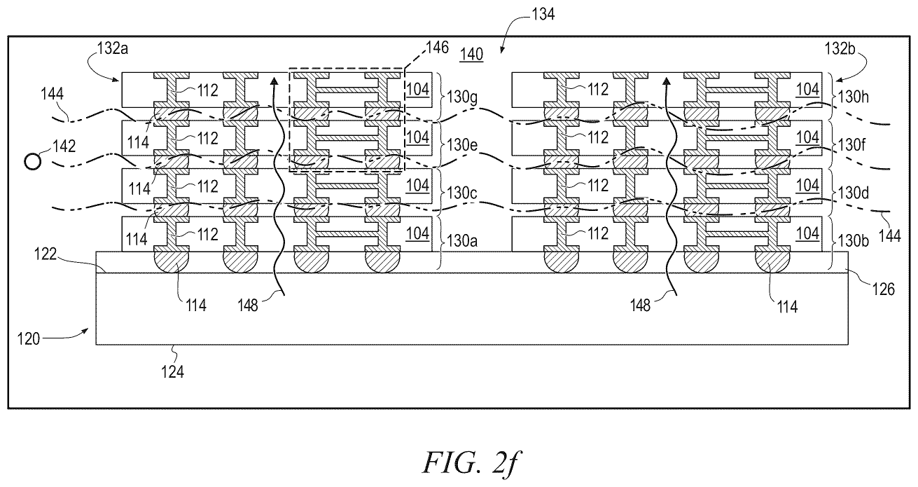

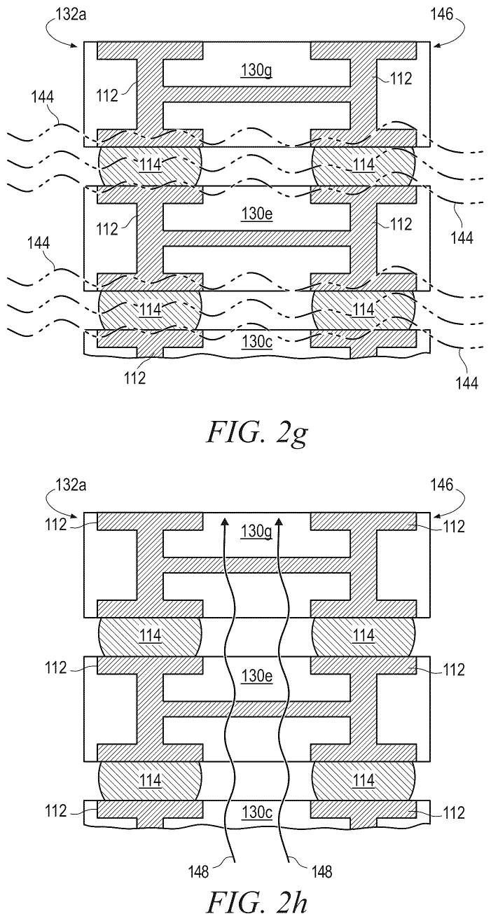

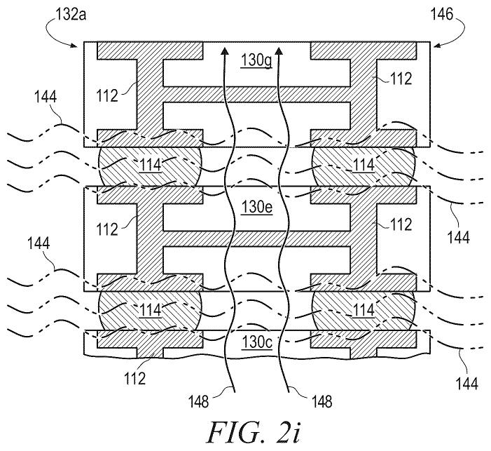

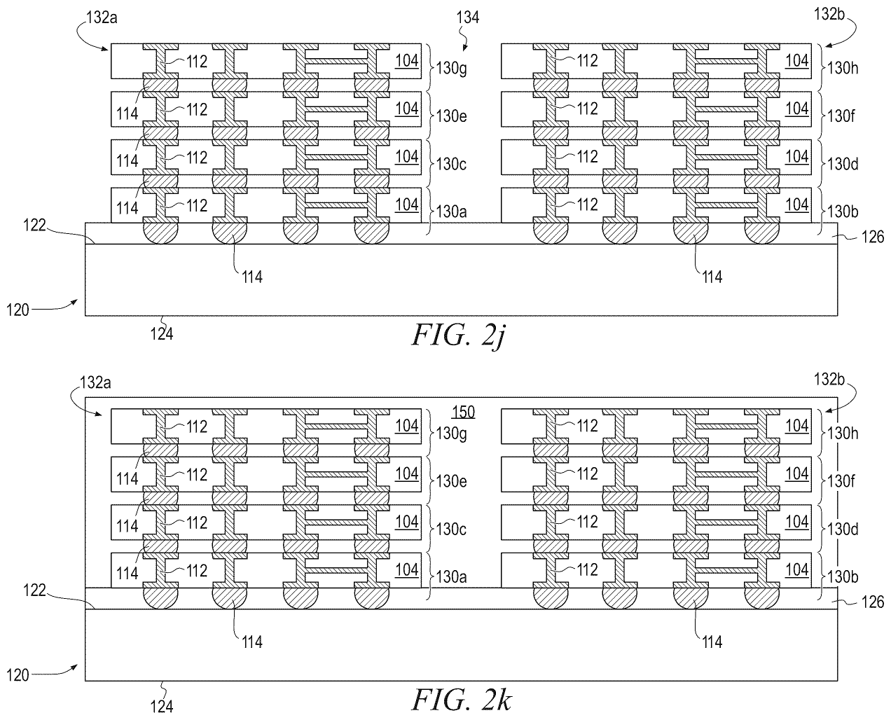

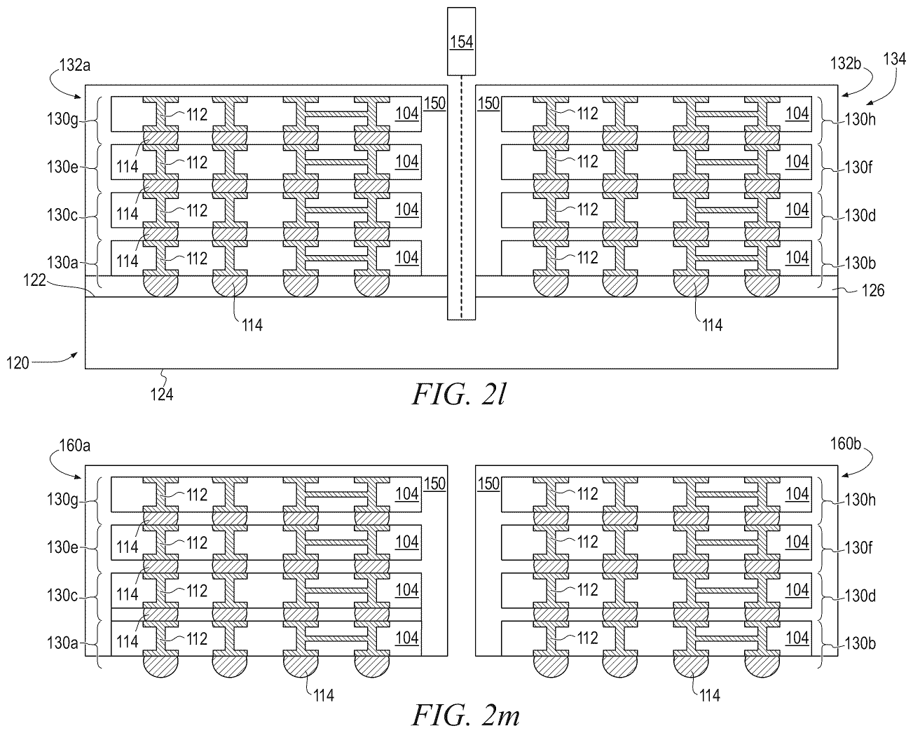

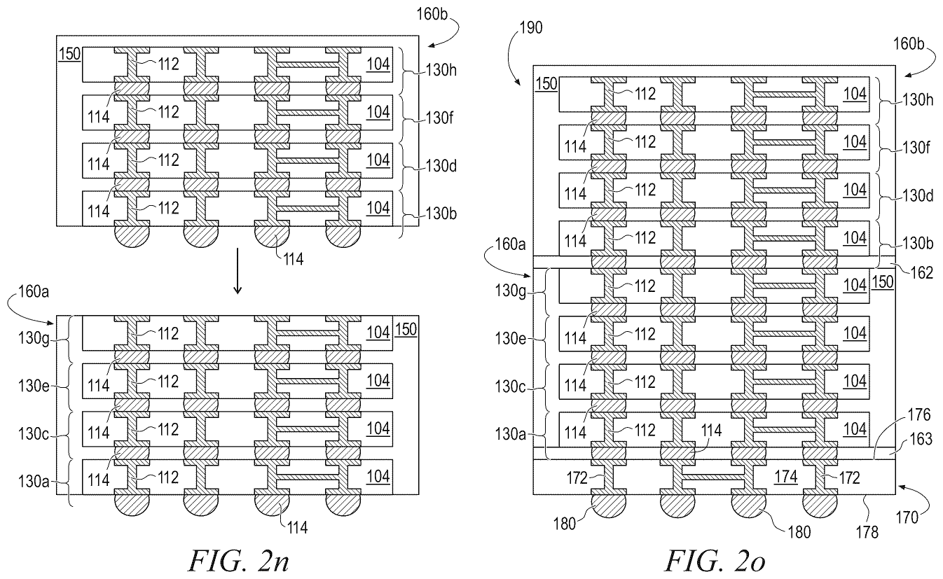

FIGS. 2a-20 illustrate a process of bonding a plurality of stacked electrical components using VFM. FIG. 2a shows a cross-sectional view of temporary substrate or carrier 120 including top surface 122 and bottom surface 124. Substrate 120 can be a sacrificial base material, such as silicon, polymer, beryllium oxide, glass, or other suitable low-cost, rigid material for structural support. In one embodiment, substrate 120 is a metal material, such as Cu, with high heat transfer capability. Substrate 120 can be used as a heat source, or a heat transfer intermediary from a heat source. An interface material 126 is disposed over surface 122 of substrate 120. Interface material 126 can be a polymer, epoxy, acryl-based B-stage material, or other similar material with penetrable properties.

In FIG. 2b, electrical component 130a and electrical component 130b are disposed over surface 122 of substrate 120 using a pick and place operation. Hybrid flux material 116 and bumps 114 make contact with surface 122. Electrical components 130a-130b are pressed into or against interface material 126 with force F1 to compress hybrid flux material 116 against surface 122 and hold electrical components 130a-130b in place. In another embodiment, hybrid flux material 116 can be deposited over surface 122 of substrate 120 prior to mounting electrical components 130a-130b.

In FIG. 2c, electrical component 130c and electrical component 130d are disposed over electrical component 130a and electrical component 130b, respectively, using a pick and place operation. Hybrid flux material 116 of electrical components 130c-130d makes contact with surface 108 of electrical components 130a-130b. Electrical components 130c-130d are pressed against electrical components 130a-130b with force F1, similar to FIG. 2b, to compress hybrid flux material 116 against surface 108 of electrical components 130a-130b and hold electrical components 130a-130d in place.

In FIG. 2d, electrical component 130e and electrical component 130f are disposed over electrical component 130c and electrical component 130b, respectively, using a pick and place operation. Hybrid flux material 116 of electrical components 130e-130f makes contact with surface 108 of electrical components 130c-130d. Electrical components 130e-130f are pressed against electrical components 130c-130d with force F1, similar to FIG. 2b, to compress hybrid flux material 116 against surface 108 of electrical components 130e-130f and hold electrical components 130a-130f in place.

In FIG. 2e, electrical component 130g and electrical component 130h are disposed over electrical component 130c and electrical component 130b, respectively, using a pick and place operation, similar to FIG. 2d. Hybrid flux material 116 of electrical components 130g-130h makes contact with surface 108 of electrical components 130e-130f. Electrical components 130g-130h are pressed against electrical components 130e-130f with force F1, similar to FIG. 2b, to compress hybrid flux material 116 against surface 108 of electrical components 130e-130f and hold electrical components 130a-130h in place.

In one embodiment, electrical components 130a-130h are semiconductor die 104 with hybrid flux material 116 oriented toward surface 122 of substrate 120. Alternatively, electrical components 130a-130h can include other semiconductor die, semiconductor packages, surface mount devices, discrete electrical devices, interconnect structures, or IPDs. As referenced herein, electrical components 130a-130h can be a first substrate.

FIGS. 2b-2e show the stacking of two columns 132a and 132b of four electrical components 130a-130h over substrate 120 as bonding assembly 134. In fact, there can be any number of columns 132 of stacked electrical components 130, and any number of electrical components 130 stacked in each column 132 of bonding assembly 134. For example, there can be eight to twelve electrical components 130 stacked in each column 132 over substrate 120. There can be multiple rows of columns 132. Within each column 132, electrical components 130 are electrically interconnected by conductive layer 112. In column 132a, electrical component 130a is electrically connected to electrical components 130c, which is electrically connected to electrical component 130e, which is electrically connected to electrical component 130g. In column 132b, electrical component 130b is electrically connected to electrical components 130d, which is electrically connected to electrical component 130f, which is electrically connected to electrical component 130g, all through conductive layer 112 within the respective electrical components. In this arrangement of bonding assembly 134, the stacked electrical components 130a-130h are particularly useful in applications such as HBM packages.

The stacked electrical components 130a-130h must be bonded by fusing bumps 114 with conductive layer 112 between each mating pair of electrical components. Yet, it is important that the heat and pressure remain uniform, with minimal stress, across bumps 114 to maximize or at least enhance the molecular and atomic bonding between bumps 114 and conductive layers 112. A uniform heat distribution across the bonding interface is important to avoid stress and ensure a uniform bond. Toward that end, bonding assembly 134 is disposed in microwave source 140, as shown in FIG. 2f. Microwave source 140 has a magnetron 142 capable of transmitting microwave signals 144. In particular, magnetron 142 transmits variable frequency microwave (VFM) signals 144 to bumps 114 and conductive layers 112. In one embodiment, microwave source 140 can be a microwave oven capable of emitting heat-generating microwaves. In another embodiment, microwave source 140 is disposed on opposite sides of bonding assembly 134. Microwave source 140 can be disposed on one side of bonding assembly 134, or above or below bonding assembly 134.

Microwave source 140 emits VFM signals 144 toward bumps 114 and conductive layers 112. FIG. 2g shows further detail within box 146 from FIG. 2f with VFM signals 144 propagating around and through bumps 114 and conductive layers 112. VFM signals 144 from microwave source 140 include electromagnetic radiation in the frequency range of 300 MHz to 300 GHZ. In one embodiment, the frequency range is 4.0 GHZ-8.0 GHz, or preferably 5.7 GHZ-7.0 GHZ. VFM signals 142 change frequency in 25 milliseconds (ms) intervals to achieve the desired uniform thermal-pressure energy distribution. More specifically, microwave energy is effectively heat generated by vibrating the molecules constituting the bump and commencing the soldering process. VFM signals 144 cause molecules to rotate without breaking their bonds. The electric field causes the electron cloud around positive atomic nuclei to distort in the direction opposite to the field. Molecules with electrons then rotate following the electric field direction. As these rotating molecules collide with neighboring molecules, the energy from these collisions is converted into heat energy through friction. Hybrid flux material 116, being a polar material, can be heated by VFM signals 144. Likewise, bump 114 is heated and melted by VFM signals 144. The temperature of hybrid flux material 116 rises over bump melting temperature and effectively dissolves and mixes with the melted bump material. The components in hybrid flux material 116 combine and harden through VFM. Notably, the base material of electrical components 130a-130h are not polar material and remain unaffected by VFM signals 144. As a result, the metal constituting bump 114 melts and combines with the soldering target of conductive layer 112 to form a joint, so electrical connection can be achieved without mass reflow. The temperature level becomes uniform across bumps 114 and conductive layers 112, typically with no metal arcing between the bumps and conductive layers. VFM signals 144 make the formation of bonds between bumps 114 and conductive layers 112, in the presence of heat and/or pressure, more efficient and uniform.

In another embodiment, after applying VFM signals 144 from FIG. 2g, substrate 120 is heated by a heating source to emitting heat waves 148 vertically through columns 132a-132b. In this case, substrate 120 is a heat source or heat block. FIG. 2h shows heat waves 148 as sources of heat and pressure to assist with bond bumps 114 to conductive layers 112, after applying VFM signals 144 from FIG. 2g. In other words, apply VFM signals 144, discontinue the VFM signals, then apply heat waves 148. Heat waves 148 work to conform the materials to each other and accommodate any asperities or surface. The combination of heat and pressure facilitates atomic or molecular diffusion across the interface, forming a strong bond. In the case of solder or adhesive layers, the heat causes these layers to melt and flow, filling gaps and creating a solid joint upon cooling. The combination of VFM signals 144 first, followed by heat waves 148, provides uniform heating, i.e., from different directions, and precise temperature control.

In another embodiment, substrate 120 is heated by a heating source to emit heat waves 148 vertically through columns 132a-132b. FIG. 2i shows VFM signals 144 in combination with heat waves 148 as simultaneously-applied sources of heat and pressure to bond bumps 114 to conductive layers 112. Heat waves 148 work to conform the materials to each other and accommodate any asperities or surface. The combination of heat and pressure facilitates atomic or molecular diffusion across the interface, forming a strong bond. In the case of solder or adhesive layers, the heat causes these layers to melt and flow, filling gaps and creating a solid joint upon cooling. The combination of VFM signals 144 with heat waves 148 provides uniform heating, i.e., from different directions, and precise temperature control.

In any case, FIG. 2j shows electrical components 130a-130h, outside microwave source 140, bonded together with bumps 114 electrically and mechanically connected between conductive layers 112 using VFM signals 144 from microwave source 140, or VFM signals 144 followed by heat waves 148, or in VFM signals 144 in combination with heat waves 148, to achieve a uniform heat-pressure distribution. The uniform heat-pressure distribution across the bonding interface avoids stresses, tilting, slippage, and warpage noted in the background, while ensuring a uniform bond. The heat-generating VFM signal 144 does not heat electrical components 130a-130h so these structures do not warp. The volumetric heating characteristic enables efficient control of heat distribution.

In FIG. 2k, encapsulant or molding compound 150 is deposited over and around columns 132a-132b of electrical components 130a-130h, as well as surface 122, using a paste printing, compressive molding, transfer molding, liquid encapsulant molding, vacuum lamination, spin coating, or other suitable applicator. Encapsulant 150 can be polymer composite material, such as epoxy resin with filler, epoxy acrylate with filler, or polymer with proper filler. Encapsulant 150 is non-conductive, provides structural support, and environmentally protects the semiconductor device from external elements and contaminants.

In FIG. 2l, encapsulant 150 is singulated between columns 132a-132b of electrical components 130a-130h using a saw blade or laser cutting tool 154. In FIG. 2m, substrate 120 and interface material 126 are removed by chemical etching, chemical mechanical polishing (CMP), mechanical peel-off, mechanical grinding, thermal bake, ultra-violet (UV) light, or wet stripping to expose bumps 114 of electrical components 130a and 130b. Semiconductor package 160a and semiconductor package 160b are shown, post singulation and substrate removal, having improved interconnect bonding with bumps 114 electrically and mechanically connected between conductive layers 112 using VFM signals 144 from microwave source 140, or VFM signals 144 followed by heat waves 148, or in VFM signals 144 in combination with heat waves 148, to achieve a uniform heat-pressure distribution and avoid tilting, slippage, and warpage noted in the background.

In FIG. 2n, semiconductor package 160b is disposed over semiconductor package 160a. A portion of encapsulant 150 is removed from semiconductor package 160a by grinding or laser direct ablation (LDA) to expose conductive layer 112. bumps 114 of semiconductor package 160b is brought into contact with conductive layer 112 of semiconductor package 160b and mechanically and electrically bonded using VFM signals 144, and/or thermal-compression bonding, as described in FIGS. 2g-2i.

FIG. 20 shows semiconductor package 160b bonded to semiconductor package 160a. An underfill material 162, such as an epoxy resin, is deposited between semiconductor package 160a and semiconductor package 160b. Likewise, an underfill material 163, such as an epoxy resin, is deposited between semiconductor package 160a and substrate 170.

FIG. 20 further shows a cross-sectional view of interconnect substrate or interposer 170 including one or more conductive layers 172 and one or more insulating layers 174. Conductive layers 172 can be one or more layers of Al, Cu, Sn, Ni, Au, Ag, or other suitable electrically conductive material. Conductive layers 172 can be formed using PVD, CVD, electrolytic plating, electroless plating process, or other suitable metal deposition process. Conductive layers 172 provide horizontal electrical interconnect across substrate 170 and vertical electrical interconnect between top surface 176 and bottom surface 178 of substrate 170. Portions of conductive layers 172 can be electrically common or electrically isolated depending on the design and function of electrical components 130a-130h. Insulating layers 174 contain one or more layers of silicon dioxide (SiO₂), silicon nitride (Si₃N₄), silicon oxynitride (SiON), tantalum pentoxide (Ta₂O₅), aluminum oxide (Al₂O₃), solder resist, polyimide, benzocyclobutene (BCB), polybenzoxazoles (PBO), and other material having similar insulating and structural properties. Insulating layers 174 can be formed using PVD, CVD, printing, lamination, spin coating, spray coating, sintering or thermal oxidation. Insulating layers 174 provide isolation between conductive layers 172. There can be multiple conductive layers like 172 separated by insulating layers 174.

The stacked semiconductor packages 160a-160b are bonded to conductive layer 172 on surface 176 of interconnect substrate 170 using VFM signals 144, and/or thermal-compression bonding, as described in FIGS. 2g-2i. An electrically conductive bump material is deposited over conductive layer 172 on surface 178 of interconnect substrate 170 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 172 using a suitable attachment or bonding process. In one embodiment, the bump material is reflowed by heating the material above its melting point to form balls or bumps 180. In one embodiment, bump 180 is formed over a UBM having a wetting layer, barrier layer, and adhesive layer. Bump 180 can also be compression bonded or thermocompression bonded to conductive layer 172. Bump 180 represents one type of interconnect structure that can be formed over conductive layer 172. The interconnect structure can also use bond wires, conductive paste, stud bump, micro bump, or other electrical interconnect.

The combination of stacked semiconductor packages 160a-160b and interconnect substrate 170 constitute HBM package 190.

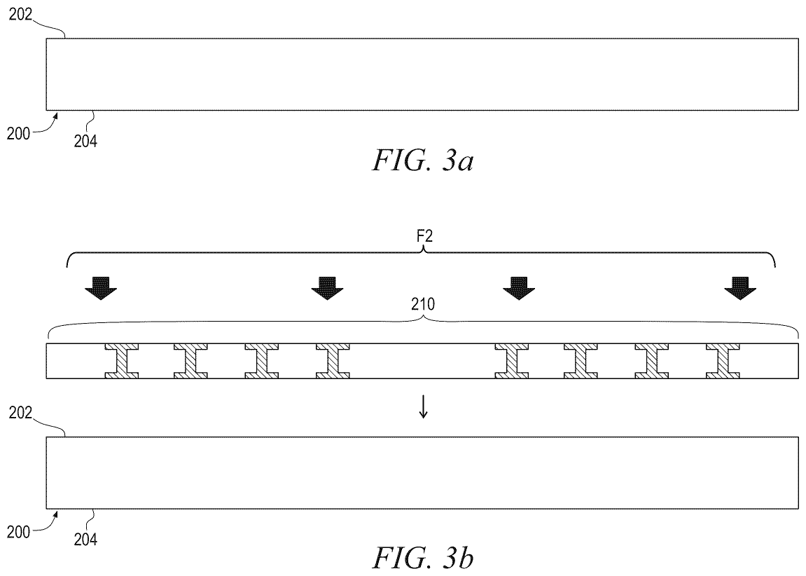

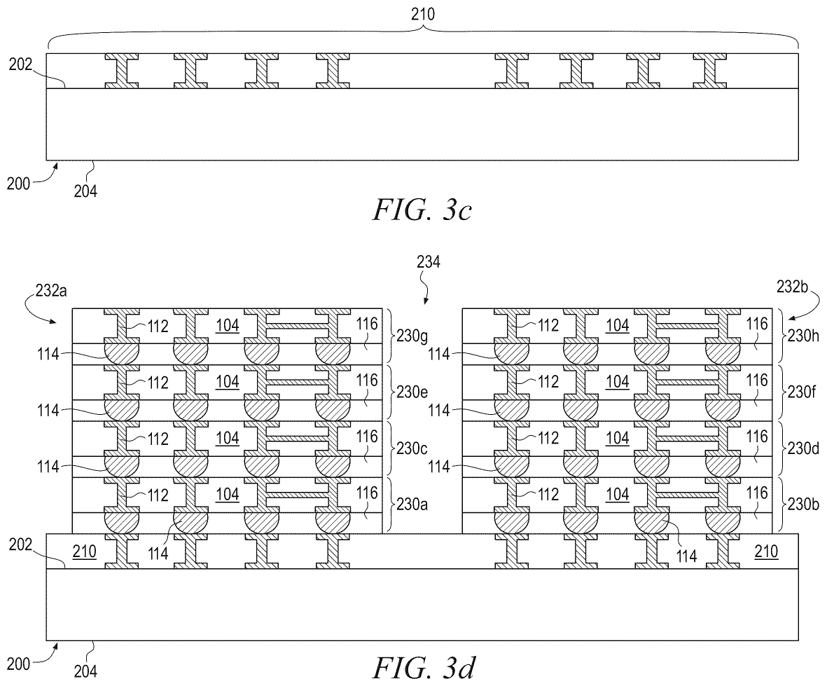

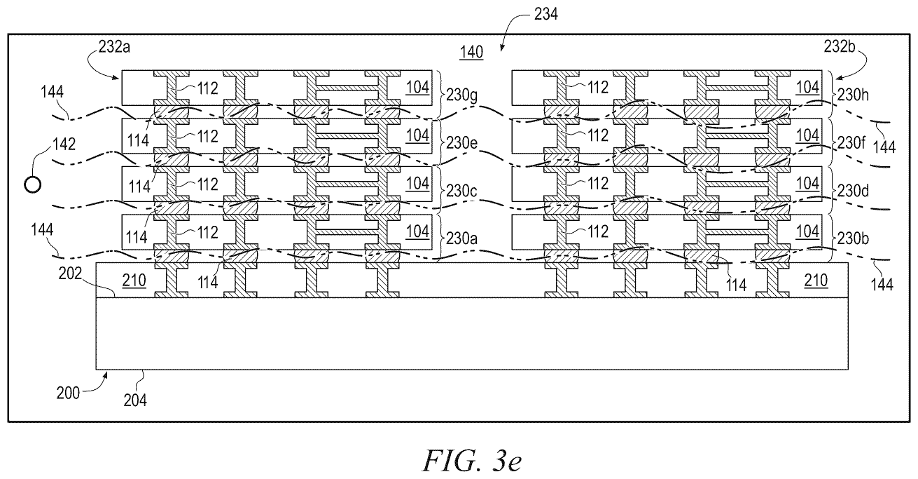

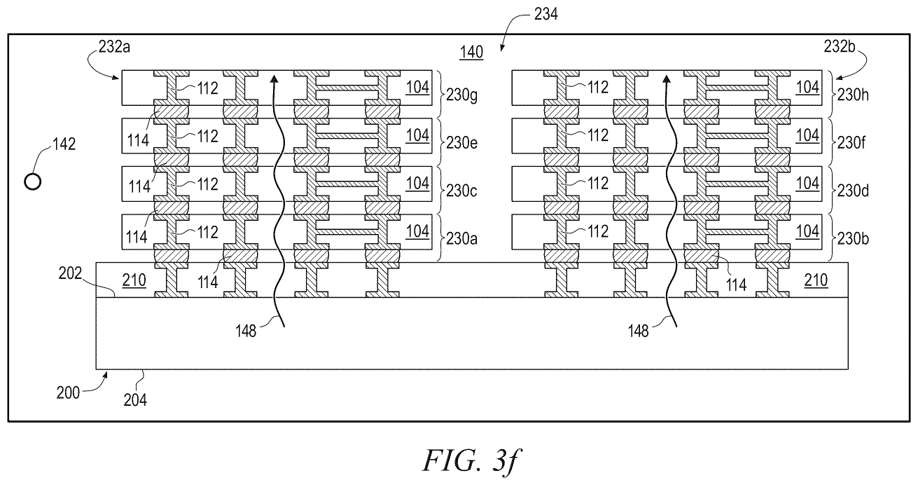

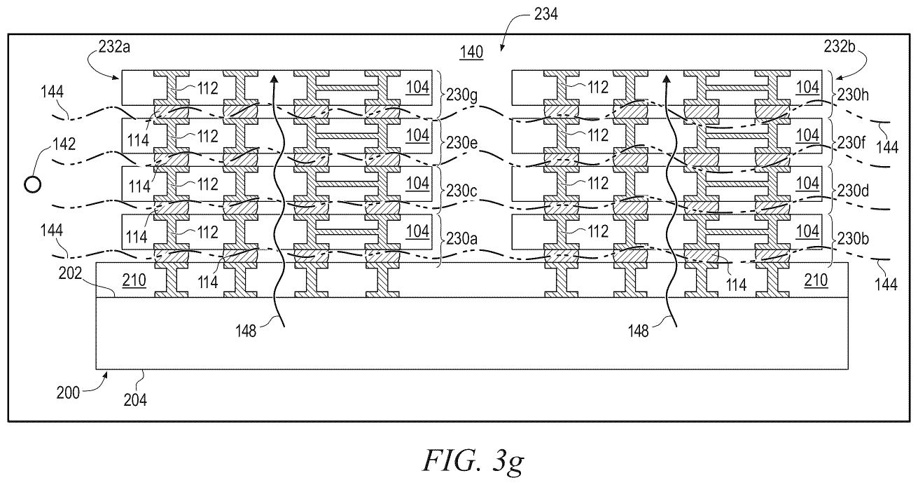

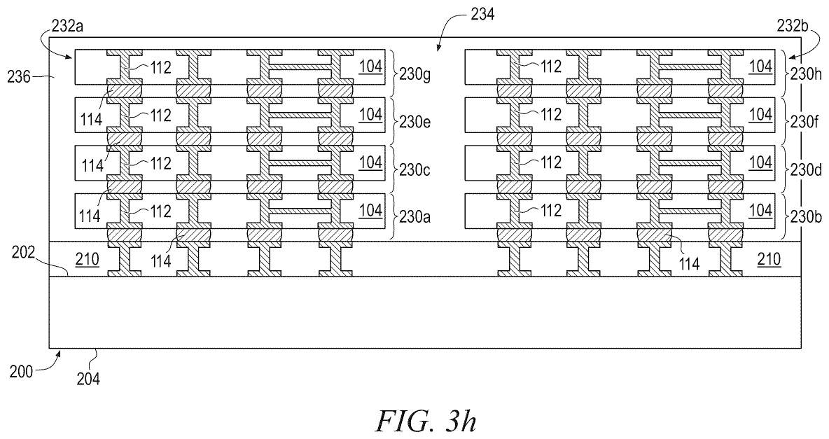

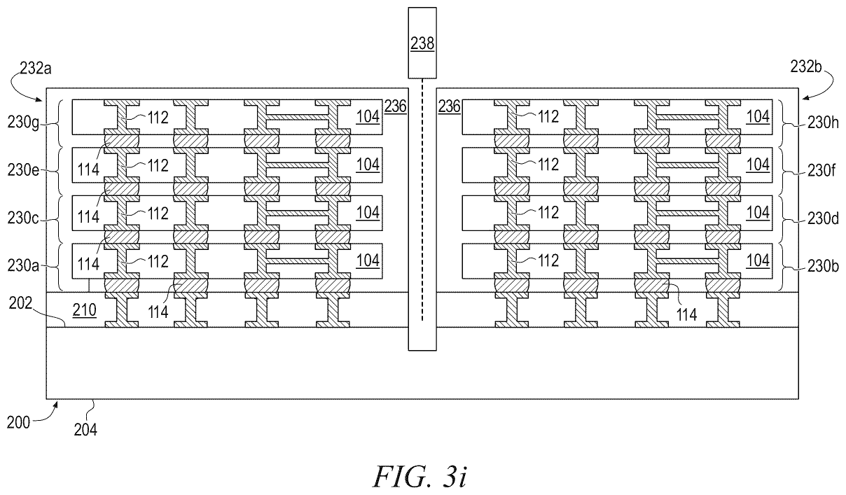

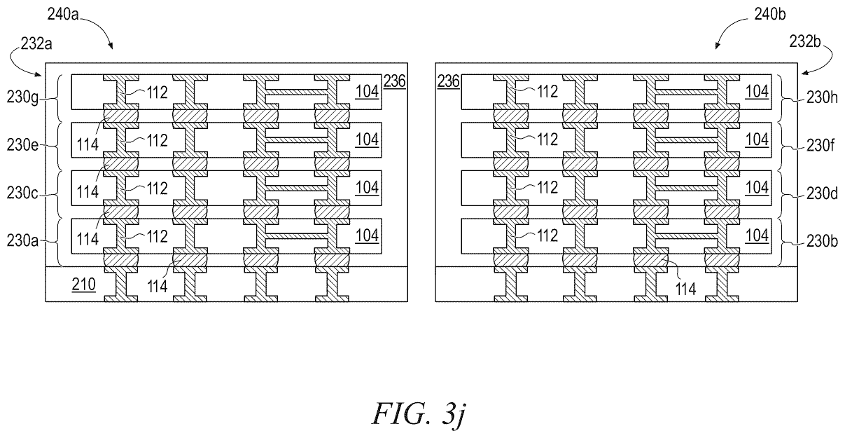

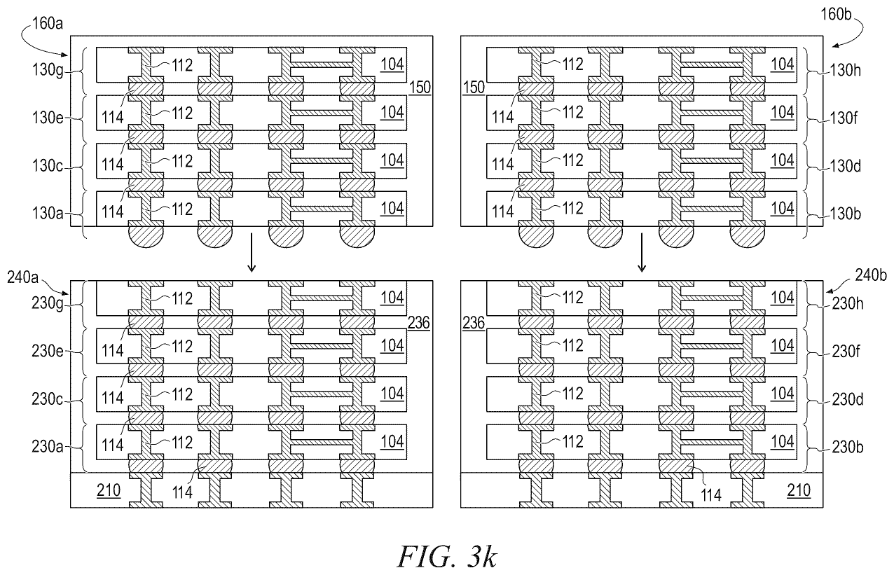

FIGS. 3a-31 illustrate a process of bonding a plurality of stacked electrical components to a semiconductor wafer using VFM. FIG. 3a shows a cross-sectional view of temporary substrate or carrier 200 including top surface 202 and bottom surface 204. Substrate 200 can be a sacrificial base material, such as silicon, polymer, beryllium oxide, glass, or other suitable low-cost, rigid material for structural support. In one embodiment, substrate 200 is a metal material, such as Cu, with high heat transfer capability. Substrate 200 can be used as a heat source, or a heat transfer intermediary from a heat source.

In FIG. 3b, semiconductor wafer 210 is disposed over surface 202 of substrate 200 using a pick and place operation. In one embodiment, semiconductor wafer 210 is similar to semiconductor wafer 100 from FIG. 1c. Alternatively, semiconductor wafer 210 can be a control die. In this case, a control die may control stacked memory modules disposed over the control die and communicate with other logic dies.

Semiconductor wafer 210 is brought into contact with surface 202 and secured with an adhesive using force F2. FIG. 3c shows semiconductor wafer 200 temporarily bonded to surface 202 of substrate 200.

In FIG. 3d, a plurality of electrical components 230a-230h are stacked over semiconductor wafer 210, similar to electrical components 130a-130h in FIGS. 2b-2i, leaving two columns 232a and 232b of four electrical components 230a-230h over semiconductor wafer 210 as bonding assembly 234. In one embodiment, electrical components 230a-230h can be semiconductor die 104 with hybrid flux material 116 from FIG. 1f.

Alternatively, electrical components 230a-230h can include other semiconductor die, semiconductor packages, surface mount devices, discrete electrical devices, interconnect structures, or IPDs. In fact, there can be any number of columns 232 of stacked electrical components 230, and any number of electrical components 230 stacked in each column 232 of bonding assembly 234. For example, there can be eight to twelve electrical components 230 stacked in each column 232 over semiconductor wafer 210. There can be multiple rows of columns 232. Within each column 232, electrical components 230 are electrically interconnected by conductive layer 112. In column 232a, electrical component 230a is electrically connected to electrical components 230c, which is electrically connected to electrical component 230e, which is electrically connected to electrical component 230g. In column 232b, electrical component 230b is electrically connected to electrical components 230d, which is electrically connected to electrical component 230f, which is electrically connected to electrical component 230g, all through conductive layer 112 within the respective electrical components. In this arrangement of bonding assembly 234, the stacked electrical components 230a-230h are particularly useful in applications such as HBM packages.

The stacked electrical components 230a-230h must be bonded by fusing bumps 114 with conductive layer 112 between each mating pair of electrical components. Yet, it is important that the heat and pressure remain uniform, with minimal stress, across bumps 114 to maximize or at least enhance the molecular and atomic bonding between bumps 114 and conductive layers 112. Toward that end, bonding assembly 234 is disposed in microwave source 140, as shown in FIG. 3e and similar to FIG. 2f. Components having a similar function are assigned the same reference number. Microwave source 140 has a magnetron 142 capable of transmitting microwave signals 144. In particular, magnetron 142 transmits VFM signals 144 to bumps 114 and conductive layers 112, as described in FIGS. 2f-21. FIG. 3e shows bumps 114 and conductive layers 112 subjected to VFM signals, as in FIG. 2g. FIG. 3f shows bumps 114 and conductive layers 112 subjected to heat waves 148, after application of VFM signals, as in FIG. 2h. FIG. 3g shows bumps 114 and conductive layers 112 simultaneously subjected to VFM signals 144 and heat waves 148, as in FIG. 2i.

In any case, FIG. 3h shows electrical components 230a-230h, outside microwave source 140, bonded together with bumps 114 electrically and mechanically connected between conductive layers 112 using VFM signals 144 from microwave source 140, or VFM signals 144 followed by heat waves 148, or in VFM signals 144 in combination with heat waves 148, to achieve a uniform heat-pressure distribution. The uniform heat-pressure distribution across the bonding interface avoids stresses, tilting, slippage, and warpage noted in the background, while ensuring a uniform bond. The heat-generating VFM signal 144 does not heat electrical components 230a-230h so these structures do not warp. The volumetric heating characteristic enables efficient control of heat distribution.

Encapsulant or molding compound 236 is deposited over and around columns 232a-232b of electrical components 230a-230h, as well as surface 202, using a paste printing, compressive molding, transfer molding, liquid encapsulant molding, vacuum lamination, spin coating, or other suitable applicator. Encapsulant 236 can be polymer composite material, such as epoxy resin with filler, epoxy acrylate with filler, or polymer with proper filler. Encapsulant 236 is non-conductive, provides structural support, and environmentally protects the semiconductor device from external elements and contaminants.

In FIG. 3i, encapsulant 236 is singulated between columns 232a-232b of electrical components 230a-230h using a saw blade or laser cutting tool 238. In FIG. 3j, substrate 200 is removed by chemical etching, CMP, mechanical peel-off, mechanical grinding, thermal bake, UV light, or wet stripping to expose conductive layer 112 of semiconductor wafer 210. Semiconductor package 240a and semiconductor package 240b are shown, post singulation and substrate removal, having improved interconnect bonding with bumps 114 electrically and mechanically connected between conductive layers 112 using VFM signals 144 from microwave source 140, or VFM signals 144 followed by heat waves 148, or in VFM signals 144 in combination with heat waves 148, to achieve a uniform heat-pressure distribution. The uniform heat-pressure distribution across the bonding interface avoids stresses, tilting, slippage, and warpage noted in the background, while ensuring a uniform bond.

In FIG. 3k, semiconductor package 160a from FIG. 2m is disposed over semiconductor package 240a, and semiconductor package 160b is disposed over semiconductor package 240b. A portion of encapsulant 236 is removed from semiconductor package 240a by grinding or LDA to expose conductive layer 112. Bumps 114 of semiconductor package 160a are brought into contact with conductive layer 112 of semiconductor package 240a and mechanically and electrically bonded using VFM signals 144, and/or thermal-compression bonding, as described in FIGS. 2g-2i. Likewise, bumps 114 of semiconductor package 160b are brought into contact with conductive layer 112 of semiconductor package 240b and mechanically and electrically bonded using VFM signals 144, and/or thermal-compression bonding.

FIG. 3l shows semiconductor package 160a bonded to semiconductor package 240a, and semiconductor package 160b bonded to semiconductor package 240b. An underfill material 242, such as an epoxy resin, is deposited between semiconductor package 160a and semiconductor package 240a and between semiconductor package 160b and semiconductor package 240b.

An electrically conductive bump material is deposited over conductive layer 112 on surface 108 of semiconductor wafer 210 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 246. In one embodiment, bump 246 is formed over a UBM having a wetting layer, barrier layer, and adhesive layer. Bump 246 can also be compression bonded or thermocompression bonded to conductive layer 112. Bump 246 represents one type of interconnect structure that can be formed over conductive layer 112. The interconnect structure can also use bond wires, conductive paste, stud bump, micro bump, or other electrical interconnect.

The combination of stacked semiconductor packages 160a-160b and semiconductor package 240a-240b constitute HBM package 250.

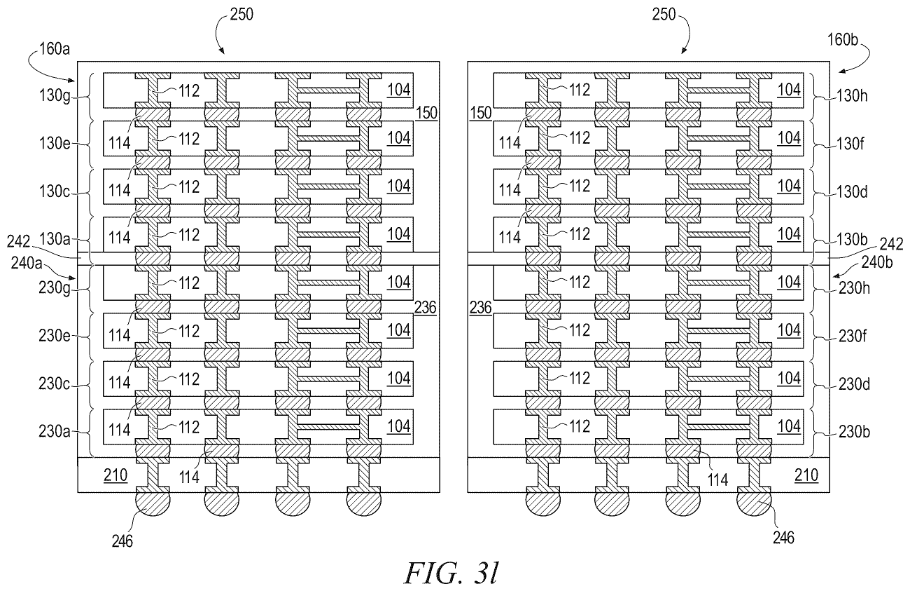

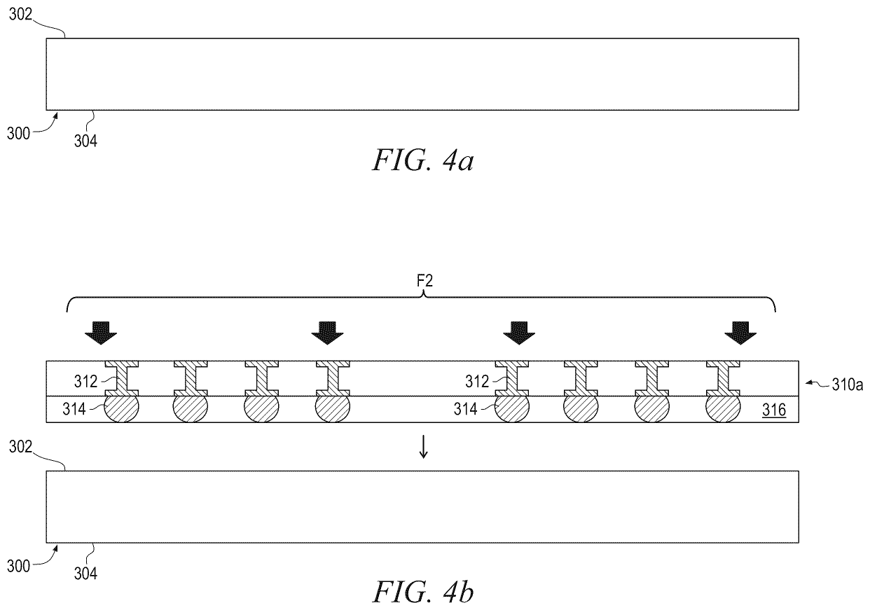

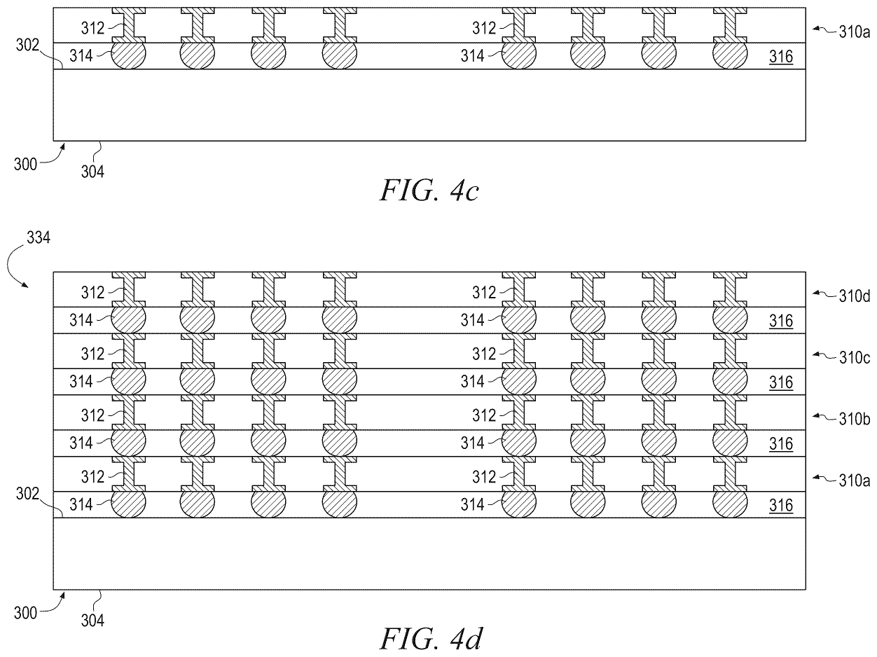

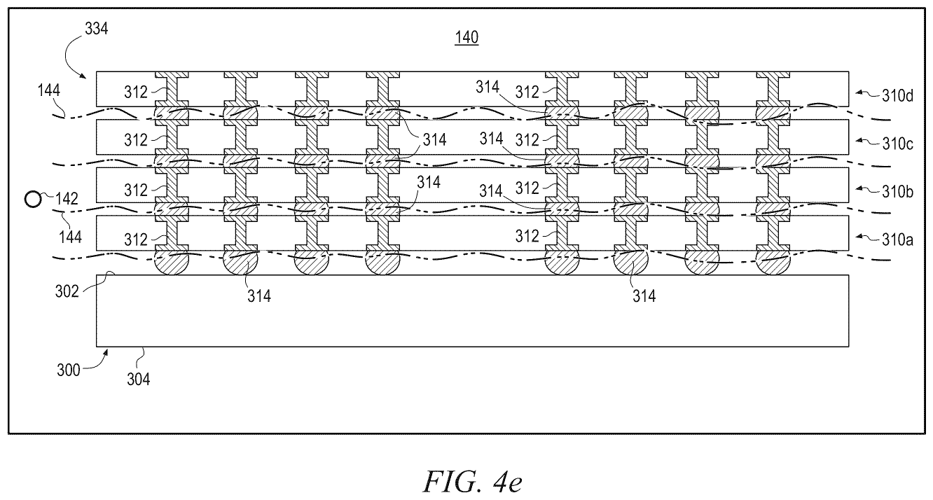

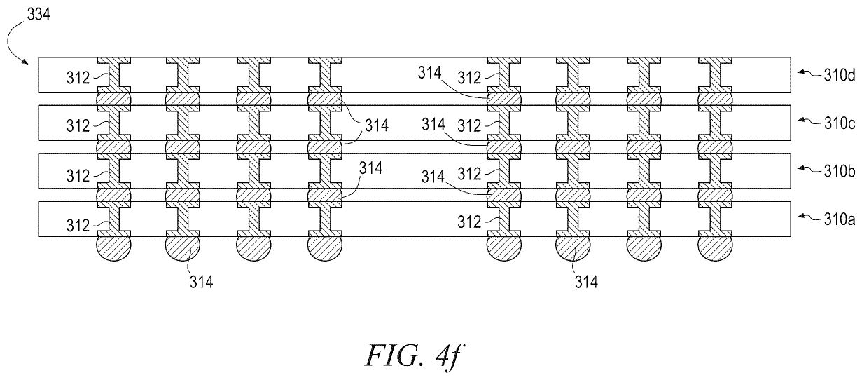

FIGS. 4a-4f illustrate a process of bonding a plurality of stacked semiconductor wafers using VFM. FIG. 4a shows a cross-sectional view of temporary substrate or carrier 300 including top surface 302 and bottom surface 304. Substrate 300 can be a sacrificial base material, such as silicon, polymer, beryllium oxide, glass, or other suitable low-cost, rigid material for structural support. In one embodiment, substrate 300 is a metal material, such as Cu, with high heat transfer capability.

In FIG. 4b, semiconductor wafer 310a is disposed over surface 302 of substrate 300 using a pick and place operation. Semiconductor wafer 310a is brought into contact with surface 302 and secured with an adhesive using force F3. FIG. 4c shows semiconductor wafer 310a temporarily bonded to surface 302 of substrate 300.

In FIG. 4d, a plurality of semiconductor wafers 310b-310d are stacked over semiconductor wafer 310a, similar to electrical components 130a-130h in FIGS. 2b-2i, leaving bonding assembly 334. In one embodiment, semiconductor wafers 310a-310d are similar to semiconductor wafer 100 from FIG. 1c. In fact, there can be any number of stacked semiconductor wafers 310 in bonding assembly 334. For example, there can be eight to twelve stacked semiconductor wafers 310 over substrate 300.

Semiconductor wafers 310a-310d are electrically interconnected by conductive layer 112. Semiconductor wafer 310a is electrically connected to semiconductor wafer 310b, which is electrically connected to semiconductor wafer 310c, which is electrically connected to electrical component 310d, all through conductive layer 312. In this arrangement of bonding assembly 334, the stacked semiconductor wafers 310a-310d are particularly useful in applications such as HBM packages.

The stacked electrical wafers 310a-310d must be bonded by fusing bumps 314 with conductive layer 312 between each mating pair of semiconductor wafers. Yet, it is important that the heat and pressure remain uniform, with minimal stress, across bumps 114 to maximize or at least enhance the molecular and atomic bonding between bumps 314 and conductive layers 312. Toward that end, bonding assembly 334 is disposed in microwave source 140, as shown in FIG. 4e and similar to FIG. 2f. Microwave source 140 has a magnetron 142 capable of transmitting microwave signals 144. In particular, magnetron 142 transmits VFM signals 144 to bumps 314 and conductive layers 312, as described in FIGS. 2f-21. Bumps 314 and conductive layers 132 are subjected to VFM signals 144, as described in FIG. 2g. Alternatively, bumps 314 and conductive layers 312 can be subjected to heat waves 148, after application of VFM signals 144, as in FIG. 2h, or bumps 314 and conductive layers 312 can be simultaneously subjected to VFM signals 144 and heat waves 148, as described in FIG. 2i.

In any case, FIG. 4f shows stacked semiconductor wafers 310a-310d, outside microwave source 140, bonded together with bumps 314 electrically and mechanically connected between conductive layers 312 using VFM signals 144 from microwave source 140, or VFM signals 144 followed by heat waves 148, or in VFM signals 144 in combination with heat waves 148, to achieve a uniform heat-pressure distribution, while avoiding tilting, slippage, and warpage noted in the background. The heat-generating VFM signal 144 does not heat semiconductor wafers 310a-310d so these structures do not warp. The volumetric heating characteristic enables efficient control of heat distribution.

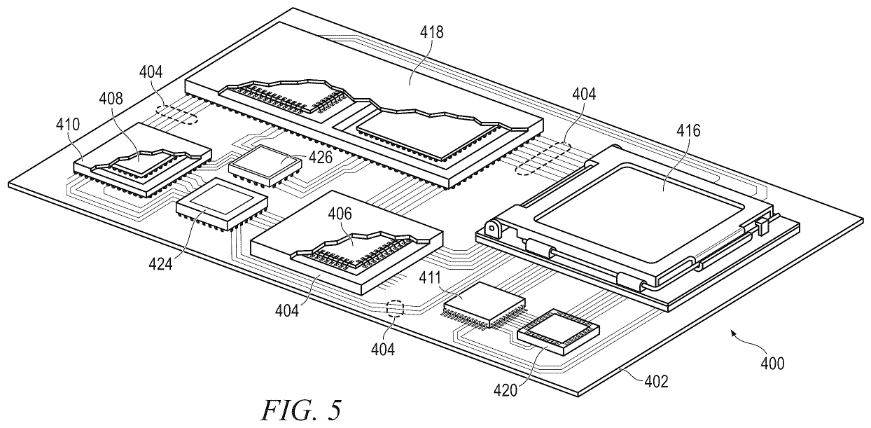

FIG. 5 illustrates electrical device 400 having a chip carrier substrate or PCB 402 with a plurality of semiconductor packages disposed on a surface of PCB 402, including HBM semiconductor packages 190 and 250. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 5, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first electrical component;
providing a second electrical component;
depositing a hybrid flux material over the first electrical component or second electrical component;
stacking the second electrical component over the first electrical component; and
forming an interconnect structure between the first electrical component and second electrical component using a variable frequency microwave.

2. The method of claim 1, further including applying heat to the interconnect structure while using the variable frequency microwave.

3. The method of claim 1, further including applying heat to the interconnect structure.

4. The method of claim 1, wherein the interconnect structure includes a bump.

5. The method of claim 1, further including depositing an encapsulant over the first electrical component and second electrical component.

6. The method of claim 1, wherein the hybrid flux material includes a flux material with a non-conductive film or non-conductive paste.

7. A method of making a semiconductor device, comprising:
providing a first substrate;
providing a second substrate;
depositing a hybrid flux material over the first substrate or second substrate;
stacking the second substrate over the first substrate; and
forming an interconnect structure between the first substrate and second substrate using a variable frequency microwave.

8. The method of claim 7, further including applying heat to the interconnect structure.

9. The method of claim 7, wherein the interconnect structure includes a bump.

10. The method of claim 7, wherein the first substrate includes a semiconductor wafer.

11. The method of claim 7, wherein the second substrate includes an electrical component.

12. The method of claim 7, further including depositing an encapsulant over the first substrate and second substrate.

13. The method of claim 7, wherein the hybrid flux material includes a flux material with a non-conductive film or non-conductive paste.

14. A semiconductor device, comprising:
a first electrical component;
a second electrical component;
a hybrid flux material deposited over the first electrical component or second electrical component, wherein the second electrical component is stacked over the first electrical component; and
an interconnect structure disposed between the first electrical component and second electrical component with a variable frequency microwave.

15. The semiconductor device of claim 14, wherein the interconnect structure is disposed between the first electrical component and second electrical component with heat.

16. The semiconductor device of claim 14, wherein the interconnect structure includes a bump.

17. The semiconductor device of claim 14, wherein the second electrical component includes a semiconductor die.

18. The semiconductor device of claim 14, further including an encapsulant deposited over the first electrical component and second electrical component.

19. The semiconductor device of claim 14, wherein the hybrid flux material includes a flux material with a non-conductive film or non-conductive paste.

20. A semiconductor device, comprising:
a first substrate;
a second substrate;
a hybrid flux material deposited over the first substrate or second substrate, wherein the second substrate is stacked over the first substrate; and
an interconnect structure disposed between the first substrate and second substrate with a variable frequency microwave.

21. The semiconductor device of claim 20, further including applying heat to the interconnect structure.

22. The semiconductor device of claim 20, wherein the interconnect structure includes a bump.

23. The semiconductor device of claim 20, wherein the first substrate includes a semiconductor wafer.

24. The semiconductor device of claim 20, wherein the second substrate includes an electrical component.

25. The semiconductor device of claim 20, further including an encapsulant deposited over the first substrate and second substrate.
